(19) United States
(12) Patent Application Publication
(10) Pub. No.: US 2019/0342952 A1
(43) Pub. Date: Nov. 7, 2019

(54) SAMPLE HOLDER

(71) Applicant: KYOCERA Corporation, Kyoto-shi, Kyoto (JP)

(72) Inventors: Yasunori IIJIMA, Kusatsu-shi (JP); Tomoya TAKASAKI, Kirishima-shi (JP)

(73) Assignee: KYOCERA Corporation, Kyoto-shi, Kyoto (JP)

(21) Appl. No.: 16/476,889

(22) PCT Filed: Dec. 27, 2017
(86) PCT No.: PCT/JP2017/046917

§ 371 Date: Jul. 10, 2019

(30) Foreign Application Priority Data
Jan. 19, 2017 (JP) 2017-007203
Oct. 26, 2017 (JP) 2017-207379

(51) Int. Cl. H05B 3/74; H05B 3/10; H01L 21/683

(52) U.S. Cl. CPC H05B 3/74; G01N 2001/002; H01L 21/683; H05B 3/10

(57) ABSTRACT

A sample holder includes: a ceramic substrate including a first circular main surface and a second circular main surface, the ceramic substrate including a first layer, a second layer and a third layer located in sequence; a conductive section located between the second layer and the third layer, the conductive section including a portion extending in a circumferential direction of the first circular main surface and a portion extending in a radial direction of the first circular main surface; a first heater located between the first layer and the second layer; and a second heater located between the second layer and the third layer and connected to the conductive section, the second heater having an annular shape which surrounds the first heater and the conductive section when viewed in a transparent plan view of the sample holder.

### CROSS-REFERENCE TO RELATED APPLICATIONS

This application is a national stage entry according to 35 U.S.C. 371 of International Application No. PCT/JP2017/046917 filed on Dec. 27, 2017, which claims priority to Japanese Patent Application Nos. 2017-007203 filed on Jan. 19, 2017, and 2017-207379 filed on Oct. 26, 2017, the contents of which are entirely incorporated herein by reference.

### TECHNICAL FIELD

The present invention relates to a sample holder used for holding a sample such as a semiconductor wafer or the like, in a fabrication process of a semiconductor integrated circuit or in a fabrication process of a liquid crystal display device.

### BACKGROUND

As an example of a sample holder, a substrate heating apparatus described in Japanese Unexamined Patent Publication JP-A 2008-243990 (hereinafter referred to as Patent Literature 1) is known. The substrate heating apparatus disclosed in Patent Literature 1 includes a ceramic base having a substrate placement surface, a resistive heating element embedded in an outer perimeter and a central portion inside the ceramic base, respectively, and a lead wire connected to the resistive heating element.

### SUMMARY

A sample holder according to an aspect of the disclosure includes: a ceramic substrate including a first circular main surface and a second circular main surface, the ceramic substrate including a first layer, a second layer and a third layer located in sequence; a conductive section located between the second layer and the third layer, the conductive section including a portion extending in a circumferential direction of the first circular main surface and a portion extending in a radial direction of the first circular main surface; a first heater located between the first layer and the second layer; and a second heater located between the second layer and the third layer and connected to the conductive section, the second heater having an annular shape which surrounds the first heater and the conductive section when viewed in a transparent plan view of the sample holder.

In addition, a sample holder according to an aspect of the disclosure includes: a ceramic substrate including a first circular main surface and a second circular main surface, the ceramic substrate including a first layer and a second layer; a first heater located between the first layer and the second layer; a second heater located between the first layer and the second layer, the second heater having an annular shape which surrounds the first heater; a connection portion which is connected to the second heater and is drawn out to the second circular main surface; and a conductive portion which includes one end connected to the connection section on the second circular main surface, the other end located closer to a center side of the second circular main surface than the one end, a portion extending in a circumferential direction of the first circular main surface, and a portion extending in a radial direction of the first circular main surface.

### BRIEF DESCRIPTION OF DRAWINGS

FIG. 1 is a longitudinal cross-sectional view showing an example of a sample holder according to the disclosure;

FIG. 2 is a traversal cross-sectional view of the sample holder shown in FIG. 1, showing a region where a first heater is located and a shape of a pattern thereof;

FIG. 3 is a transparent view of the sample holder shown in FIG. 1, showing a region where the first heater is located and a region where a second heater is located, and a shape of a pattern thereof;

FIG. 4 is a cross-sectional view of the sample holder shown in FIG. 1, showing a region where a conductive section is located and a shape of a pattern thereof;

FIG. 5 is a longitudinal cross-sectional view showing another example of a sample holder according to the disclosure;

FIG. 6A is a cross-sectional view of the sample holder shown in FIG. 5, showing a region where the first heater and the second heater are located, FIG. 6B is a cross-sectional view showing an example of a pattern shape of a portion of the first heater, and FIG. 6C is a cross-sectional view showing an example of a pattern shape of a portion of the second heater;

FIG. 7 is a plan view of the sample holder shown in FIG. 5, showing a region where the conductive section is located and the shape of the pattern thereof;

FIG. 8 is a longitudinal cross-sectional view showing another example of a sample holder according to the disclosure;

FIG. 9 is a plan view of the sample holder shown in FIG. 8, showing a region where a conductive section is located;

FIG. 10 is a longitudinal cross-sectional view showing another example of a sample holder according to the disclosure;

FIG. 11 is a plan view of the sample holder shown in FIG. 10, showing a region where a conductive section is located;

FIG. 12 is a longitudinal cross-sectional view showing another example of a sample holder according to the disclosure;

FIG. 13 is a plan view of the sample holder shown in FIG. 12, showing a region where a conductive section is located; and

FIG. 14 is a longitudinal cross-sectional view showing another example of a sample holder according to the disclosure.

### DETAILED DESCRIPTION

A sample holder 10 of an example of the disclosure will be described in detail.

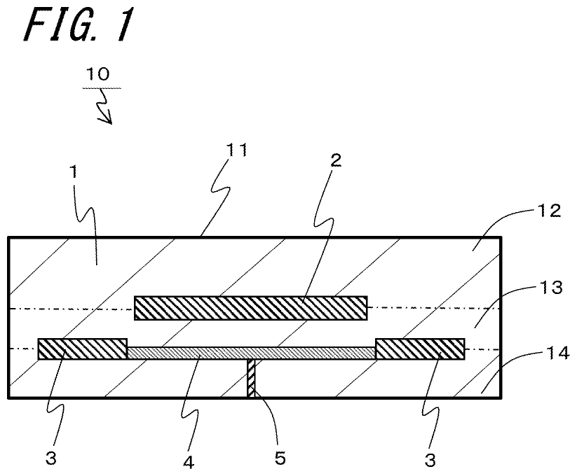

FIG. 1 is a cross-sectional view showing an example of a sample holder 10 according to the disclosure. As shown in FIG. 1, the sample holder 10 includes a ceramic substrate 1 including a first main surface and a second main surface, the ceramic substrate 1 including a first layer 12, a second layer 13 and a third layer 14, a first heater 2 located between the first layer 12 and the second layer 13, a second heater 3 located between the second layer 13 and the third layer 14, and a conductive section 4 connected to the second heater 3 and the second heater 3. Further, the second heater 3 has an annular shape which surrounds the first heater 2 and the conductive section 4 when viewed in a transparent plan view of the sample holder.

The ceramic substrate 1 is a member for holding a sample. The ceramic substrate 1 is a disk-shaped member. The ceramic substrate 1 includes the first layer 12, the second layer 13 and the third layer 14. The first layer 12, the second layer 13 and the third layer 14 are located in the order of the first layer 12, the second layer 13 and the third layer 14. The first layer 12, the second layer 13 and the third layer 14 may each include a plurality of ceramic layers. For example, the first main surface of the ceramic substrate 1 may be a sample holding surface 11. The sample holding surface 11 may be a main surface of the first layer 12, for example. In addition, the sample holding surface 11 may be a main surface of the third layer 14, for example. By way of example, a case where the first main surface of the ceramic substrate 1 is used as the sample holding surface 11 will be described below.

The ceramic substrate 1 includes a ceramic material such as aluminum nitride or alumina, for example. The ceramic substrate 1 may be obtained by laminating a plurality of green sheets and firing the laminate in nitrogen atmosphere, for example. A first heater 2 and a second heater 3 are located inside the ceramic substrate 1. In addition, an electrode for electrostatic adsorption may be located inside the ceramic substrate 1 as necessary. In order to achieve such a configuration, a pattern to be the first heater 2, the second heater 3 and the electrode for electrostatic adsorption may be printed on a desired green sheet among the plurality of green sheets before the firing described above by a screen printing method. For the dimensions of the ceramic substrate 1, the diameter of the main surface may be about 30 to 500 mm, and the thickness of the ceramic substrate 1 may be about 5 to 25 mm, for example.

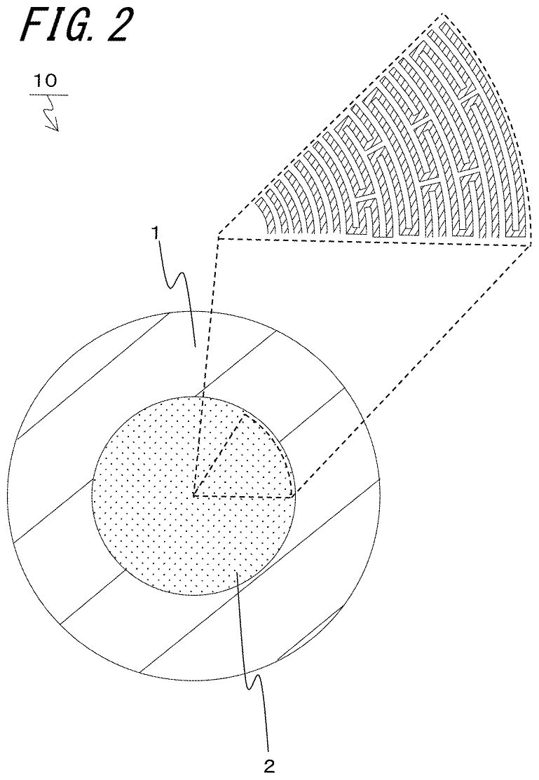

The first heater 2 is a member for heating, together with the second heater 3, the sample held on the sample holding surface 11 of the ceramic substrate 1. The first heater 2 is located between the first layer 12 and the second layer 13. A voltage may be applied to the first heater 2, resulting in heat generation in the first heater 2. The heat generated from the first heater 2 is transmitted through the inside of the ceramic substrate 1 to reach the sample holding surface 11. As a result, the sample held on the sample holding surface 11 may be heated. The first heater 2 has a linear pattern having a plurality of folds, for example. Specifically, the first heater 2 may be a linear pattern having a plurality of folds located on a circumference of a plurality of concentric circles as shown in FIG. 2.

In FIG. 2, the region where the first heater 2 is located is shown in a dot pattern, and a wiring pattern of the first heater 2 is shown with a partial enlargement of a portion thereof. The first heater 2 is formed so as to have a constant heat generation density. As a result, it is possible to suppress the occurrence of variations in heat distribution across the sample holding surface 11.

The first heater 2 may include a conductor component and a ceramic component, for example. The conductor component contains a metal material such as tungsten or tungsten carbide, for example. The ceramic component contains the same component as the ceramic substrate 1 such as aluminum nitride, for example. The dimensions of the first heater 2 may be 0.01 to 0.02 mm in thickness, 0.7 to 1.5 mm in width, and 18000 to 19000 mm in total length, for example.

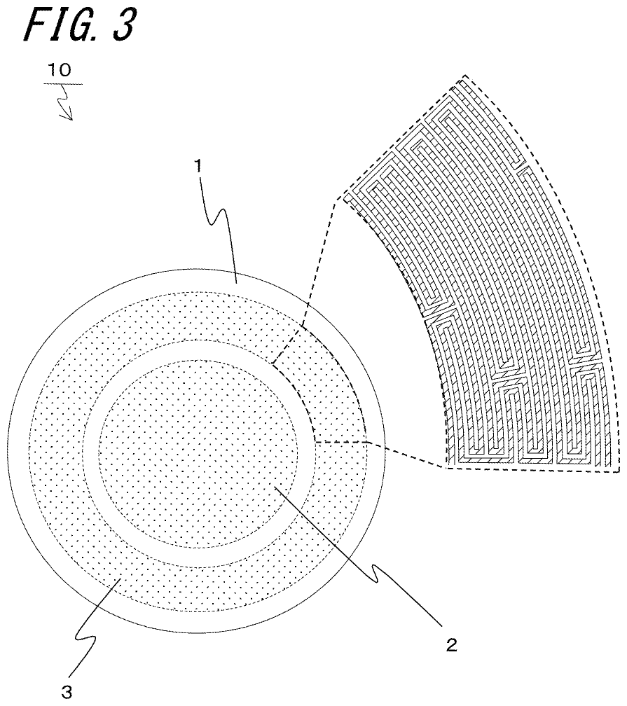

The second heater 3 is a member for heating, together with the first heater 2, the sample held on the sample holding surface 11 of the ceramic substrate 1. The second heater 3 is located between the second layer 13 and the third layer 14. As shown in FIG. 3, the second heater 3 is formed in an annular shape to surround the first heater 2 when viewed from a direction perpendicular to the sample holding surface 11. Generally, heat is more likely to be transferred at an outer perimeter side of the sample holding surface 11, than at a center side of the sample holding surface 11. In addition, since the degree of heat transfer varies depending on the external environment at the outer perimeter side of the sample holding surface 11, it is difficult to improve the uniformity in temperature with the center side of the sample holding surface 11. As shown in FIG. 3, the second heater 3 is formed in an annular shape to surround the first heater 2 so that, when the first heater 2 and the second heater 3 are independently controlled, the outer perimeter side of the sample holder 10 may be heated according to the degree of heat transfer. As a result, the temperature uniformity of the sample holding surface 11 may be enhanced.

In FIG. 3, the region where the first heater 2 is located and the region where the second heater 3 is located are shown in a dot pattern, and the wiring pattern of the second heater 3 is shown with a partially enlargement of a portion thereof.

In the example, the second heater 3 includes the same material as the first heater 2, for example. The dimensions of the second heater 3 may be 0.01 to 0.04 mm in thickness, 0.7 to 1.5 mm in width, and 9000 to 22000 mm in total length, for example.

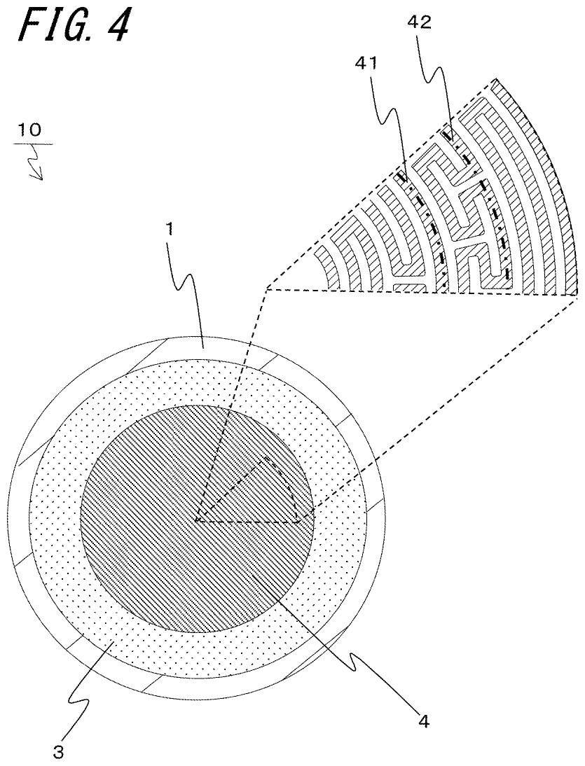

The conductive section 4 is connected to the second heater 3 in the ceramic substrate 1. The conductive section 4 is configured to electrically connect the second heater 3 and an external power supply. The conductive section 4 is located in the second heater 3 as shown in FIG. 4. In FIG. 4, the region where the conductive section 4 is located is shown in a broken line, and the wiring pattern of the conductive section 4 is shown with a partial enlargement of a part thereof.

The conductive section 4 includes a metal material such as tungsten or tungsten carbide, for example. The conductive section 4 may be formed of the same material as the first heater 2 and the second heater 3 or may be formed of a different material. When the conductive section 4 includes the same material as the second heater 3, the difference in the thermal expansion at a connection portion between the conductive section 4 and the second heater 3 may be reduced. As a result, it is possible to reduce the possibility that a crack may occur in the connection portion between the conductive section 4 and the second heater 3. When the conductive section 4 is formed of a material different from that of the second heater 3, it is preferable that the conductive section 4 is formed of a material having a volume resistivity less than that of the first heater 2 and the second heater 3. As a result, the heat generation in the conductive section 4 may be reduced. When the same material (main component) as the second heater 3 is used for the conductive section 4, a metal (subcomponent) having a small volume resistivity such as gold is added so that the volume resistivity in the conductive section 4 may be less than the volume resistivity in the second heater 3. In this example, when the conductive section 4 and the second heater 3 have 90 mass % or more of the same component, it may be considered that the conductive section 4 and the second heater 3 are formed of the same material (main component).

The dimensions of the conductive section 4 may be 0.1 to 0.04 mm in thickness, 1.0 to 3.8 mm in width, and 20000 to 22000 mm in total length, for example. In addition, the conductive section 4 in the sample holder 10 of this example is connected to a through-hole conductor 5 in the vicinity of the center of the sample holder 10 as shown in FIG. 1. One end of the through-hole conductor 5 is connected to the conductive section 4, and the other end is drawn out to the second main surface of ceramic substrate 1. The conductive section 4 is electrically connected to the external power supply through the through-hole conductor 5.

In the sample holder 10 of this example, as shown in FIG. 4, the conductive section 4 includes a portion extending in a circumferential direction of the first main surface and a portion extending in a radial direction of the first main surface. As a result, when the conductive section 4 itself generates heat, in the conductive section 4, both the portion extending in the circumferential direction of the sample holding surface 11 and the portion extending in the radial direction thereof generate heat. Therefore, compared to the example where the conductive section 4 includes only a portion extending in the radial direction of the sample holding surface 11, the region of the sample holding surface 11 to be heated by the conductive section 4 may be expanded. Therefore, the unevenness of the heat generated in the sample holding surface 11 due to the heat generation of the conductive section 4 may be suppressed. As a result, the temperature uniformity of the sample holding surface 11 may be enhanced.

In the sample holder 10 according to the embodiment, as shown in FIG. 4, the portion of the conductive section 4 extending in the circumferential direction includes a first portion 41 and a second portion 42, in which the first portion 41 is located on a circumference of a first virtual circle, and the second portion 42 is located on a circumference of a second virtual circle, and the first virtual circle and the second virtual circle may be concentric circles. As a result, when the conductive section 4 itself generates heat, the region of the sample holding surface 11 heated by the conductive section 4 may be located in an equidistance region from the center of the concentric circle. Further, when the conductive section 4 itself generates heat, the region of the sample holding surface 11 heated by the conductive section 4 may be further expanded. Therefore, the unevenness of the heat generated in the sample holding surface 11 due to the heat generation of the conductive section 4 may be suppressed. As a result, the temperature uniformity of the sample holding surface 11 may be further enhanced. In FIG. 4, portions of the first virtual circle and the second virtual circle are indicated by alternate long and short dashed lines.

In addition, the first portion 41 may be located on the entire circumference of the first virtual circle, and the second portion 42 may be located on the entire circumference of the concentric circle of the second virtual circle. Therefore, it is possible to reduce the unevenness of heat generation in the region of the sample holding surface 11 in which the conductive section 4 extends in the circumferential direction. As a result, the temperature uniformity of the sample holding surface 11 may be enhanced. In addition, by the expression “entire” used herein, it does not mean the entirety in the strict sense, but may include a clearance gap for avoiding contact with an adjacent portion of the conductive section 4 or other wiring and the like.

Further, it is preferable that the portions of the conductive section 4 extending in the circumferential direction are located at regular intervals in the radial direction. As a result, the temperature uniformity in the radial direction may be enhanced. At this time, the radial interval of the conductive sections 4 may be 3.8 mm, for example.

As shown in FIG. 4, in the sample holder 10 of the example, the conductive section 4 is located on the entire portion surrounded by the second heater 3. Thus, when the conductive section 4 itself generates heat, the entire region of the portion of the sample holding surface 11 surrounded by the heater may be heated. Therefore, the unevenness of the heat generated in the sample holding surface 11 due to the heat generation of the conductive section 4 may be suppressed. As a result, the temperature uniformity of the sample holding surface 11 may be enhanced. In addition, by the expression “entire” used herein, it does not mean the entirety in the strict sense, but may include a clearance gap for avoiding contact with an adjacent portion of the conductive section 4 or other wiring and the like.

In the sample holder 10 of the example, as shown in FIG. 1, the thickness of the conductive section 4 is less than the thickness of the second heater 3. Therefore, the interval between the conductive section 4 and the sample holding surface 11 may be increased. Therefore, even when the conductive section 4 generates heat, the timing at which the heat reaches the sample holding surface 11 may be delayed. Accordingly, immediately after the heating, the possibility that the unevenness of heat may occur on the sample holding surface 11 due to the heat generation of the conductive section 4 may be reduced. As a result, the overall temperature uniformity of the sample holding surface 11 may be further enhanced.

As a definition of the thickness of the first heater 2, when the sample holder 10 is viewed in a longitudinal cross section perpendicular to the sample holding surface 11, the average value of the thicknesses of the first heater 2 measured at five places at random may be set as the thickness of the first heater 2. As a method of measuring the thickness of the first heater 2, for example, the thickness of the first heater 2 may be obtained by scanning or irradiating with the laser using a laser displacement meter LT-8010 or LJ-V7020, and so on manufactured by Keyence Corporation in a line width direction of the first heater 2, calculating the cross-sectional area and dividing the same by the width. Further, the thickness of the second heater 3 and the conductive section 4 may also be measured by such a method.

Further, the width of the conductive section 4 may be greater than the width of the second heater 3. Accordingly, the conductive section 4 may be provided with a greater cross-sectional area than the cross-sectional area of the heater, while the conductive section 4 may be provided with a less resistance value, so that the amount of heat generation of the conductive section 4 may be reduced. Therefore, the possibility that the unevenness of heat may occur on the sample holding surface 11 due to the heat generation of the conductive section 4 may be reduced. As a result, the overall temperature uniformity of the sample holding surface 11 may be further enhanced.

Further, the interval of the pattern of the conductive sections 4 may be greater than the interval of the pattern of the second heater 3. Accordingly, when the sample holder 10 is viewed in the cross section shown in FIG. 4, the ratio of the area occupied by the conductive section 4 per unit area may be reduced. Therefore, it is possible to reduce the thermal stress generated when the conductive section 4 is thermally expanded. As a result, the durability of the sample holder 10 may be enhanced.

When the pattern of the second heater 3 is located on a plurality of virtual circles which are concentric circles, the interval between a portion provided on one virtual circle and a portion provided on another virtual circle adjacent thereto in the pattern of the second heater 3 is defined as an interval of the pattern of the second heater 3. Moreover, when the pattern of the conductive section 4 is located on a plurality of virtual circles which are concentric circles, the interval between a portion located on one virtual circle and a portion located on another virtual circle adjacent thereto in the pattern of the conductive section 4 is defined as an interval of the pattern of the conductive section 4.

Hereinafter, the sample holder 110 of another example of the disclosure will be described in detail.

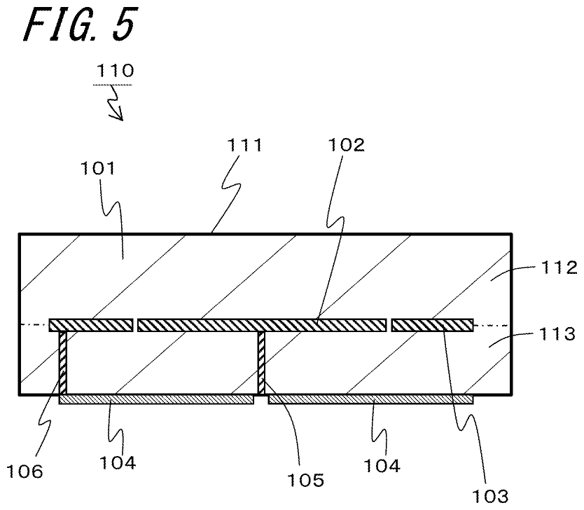

FIG. 5 is a cross-sectional view showing another example of the sample holder 110 according to the disclosure. As shown in FIG. 5, the sample holder 110 includes a ceramic substrate 101 including a first main surface and a second main surface, the ceramic substrate 101 including a first layer 112 and a second layer 113, a first heater 102 located between the first layer 112 and the second layer 113, a second heater 103 located between the first layer 112 and the second layer 113, a connection portion 106 which is connected to the second heater 103 and is drawn out to the second main surface of the ceramic substrate 101, and a conductive section 104 including one end connected to the connection portion 106 on the second main surface.

The ceramic substrate 101 is a member for holding a sample. The ceramic substrate 101 is a disk-shaped member. The ceramic substrate 101 includes a first layer 112 and a second layer 113. The first main surface of the ceramic substrate 101 may be a sample holding surface 111. Further, the surface of the first layer 112 may be the sample holder 111. By way of example, a case where the first main surface of the ceramic substrate 101 is used as the sample holding surface 111 will be described below.

The ceramic substrate 101 includes a ceramic material such as aluminum nitride or alumina, for example. The ceramic substrate 101 may be obtained by laminating a plurality of green sheets and firing the laminate in nitrogen atmosphere, for example. The first heater 102 and the second heater 103 are located inside the ceramic substrate 101. In addition, the electrode for electrostatic adsorption may be located inside the ceramic substrate 101 as necessary. In order to achieve such a configuration, a pattern to be the first heater 102, the second heater 103 and the electrode for electrostatic adsorption is printed on a desired green sheet among the plurality of green sheets before the firing described above by a screen printing method. For the dimensions of the ceramic substrate 101, the diameter of the main surface may be about 30 to 500 mm, and the thickness of the ceramic substrate 1 may be about 5 to 25 mm, for example.

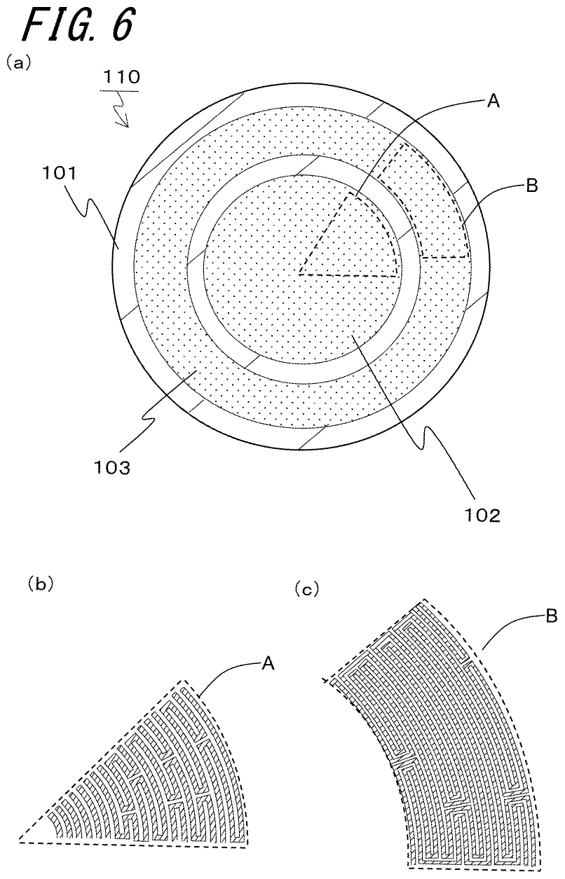

The first heater 102 is a member for heating, together with the second heater 103, the sample held on the sample holding surface 111 of the ceramic substrate 101. The first heater 102 is located between the first layer 112 and the second layer 113. A voltage may be applied to the first heater 102, resulting in heat generation in the first heater 102. The heat generated from the first heater 102 is transmitted through the inside of the ceramic substrate 101 to reach the sample holding surface 111. As a result, the sample held on the sample holding surface 111 may be heated. The first heater 102 has a linear pattern having a plurality of folds, for example. Specifically, the first heater 102 may have a linear pattern having a plurality of folds arranged concentrically as shown in FIGS. 6A to 6C.

In FIG. 6A, the region where the first heater 102 is located is shown in a dot pattern. In addition, FIG. 6B is a partial enlargement of a portion of the first heater 102, showing an example of the wiring pattern. The first heater 102 is formed so as to have a constant heat generation density. As a result, it is possible to suppress the occurrence of variations in heat distribution across the sample holding surface 111.

The first heater 102 may include a conductor component and a ceramic component, for example. The conductor component contains a metal material such as tungsten or tungsten carbide, for example. The ceramic component contains powder of the same component as the ceramic substrate 101 such as aluminum nitride, for example. The dimensions of the first heater 102 may be 0.01 to 0.02 mm in thickness, 0.7 to 1.5 mm in width, and 18000 to 19000 mm in total length, for example.

The first heater 102 may be connected to the through-hole conductor 105 in the vicinity of the center of the sample holder 110, for example, as shown in FIG. 5. At this time, one end of the through-hole conductor 105 is connected to the first heater 102 in the ceramic substrate 101, and the other end is drawn out to the second main surface of the ceramic substrate 101. As a result, the first heater 102 and the external power supply may be electrically connected such that the voltage is applied to the first heater 102.

The second heater 103 is a member for heating, together with the first heater 102, the sample held on the sample holding surface 111 of the ceramic base 101. The second heater 103 is located between the first layer 112 and the second layer 113. The second heater 103 has an annular shape that surrounds the first heater 102, as shown in FIG. 6A. Generally, heat is more likely to be transferred at an outer perimeter side of the sample holding surface 111, than at a center side of the sample holding surface 111. In addition, since the degree of heat transfer varies depending on the external environment at the outer perimeter side of the sample holding surface 111, it is difficult to improve the uniformity in temperature with the center side of the sample holding surface 111. As shown in FIG. 6A, the second heater 103 is formed in an annular shape to surround the first heater 102 so that, when the first heater 102 and the second heater 103 are independently controlled, the outer perimeter side of the sample holder 110 may be heated according to the degree of heat transfer. As a result, the temperature uniformity of the sample holding surface 111 may be enhanced.

In FIG. 6A, the region where the second heater 103 is located is shown in a dot pattern. In addition, FIG. 6C is a partial enlargement of a portion of the second heater 103, showing an example of the wiring pattern. In the example, the second heater 103 includes the same material as the first heater 102, for example. The dimensions of the second heater 103 may be 0.01 to 0.04 mm in thickness, 0.7 to 1.5 mm in width, and 9000 to 22000 mm in total length, for example.

The connection portion 106 is a member for electrically connecting the second heater 103 and the conductive section 104. The connection portion 106 is a linear member, for example. For example, the connection portion 106 may be connected by one end thereof to the second heater 103 in the ceramic substrate 101. Further, for example, the other end of the connection portion 106 is drawn out to the second main surface of the ceramic substrate 101, and is connected to the conductive section 104. For example, as shown in FIG. 5, the connection portion 106 in the ceramic substrate 101 may be located perpendicularly to the sample holding surface 111. In addition, a hole for drawing out may be located on the second main surface of the ceramic substrate 101, and the connection portion 106 may be located in the hole. The members of the connection portion 106 may be formed of an alloy material of silver, copper, titanium or the like, for example. The dimensions of the connection portion 106 may be 0.001 to 0.01 mm in thickness, 0.1 mm to 10 mm in width, and 0.1 mm to 5 mm in total length, for example.

The conductive section 104 is configured to electrically connect the center side of the second main surface of ceramic substrate 101 to the external power supply. The conductive section 104 on the second main surface of the ceramic substrate 101 is connected by one end thereof to the connection portion 106. Further, the other end of the conductive section 104 is drawn out closer to the center side of the second main surface than the one end. For example, the other end of the conductive section 104 is connected to a lead member, and is electrically connected to the external power supply through the lead member. As a result, a voltage may be applied to the second heater 103. The dimensions of the conductive section 104 may be 0.01 to 0.1 mm in thickness, 1 to 10 mm in width, and 1000 to 10000 mm in total length.

The conductive section 104 includes an alloy material of silver, copper, titanium or the like, for example. The conductive section 104 may be formed of the same material as the second heater 103 or the connection portion 106, or may be formed of a different material. When the conductive section 104 includes the same material as the connection portion 106, the difference in thermal expansion in the connection portion 106 between the conductive section 104 and the connection portion 106 may be reduced. Therefore, it is possible to reduce the possibility that a stress, which causes a crack, is applied to a portion where the conductive section 104 and the connection portion 106 are connected. When the conductive section 104 is formed of a material different from that of the second heater 103, it is preferable that the conductive section 104 is formed of a material having a volume resistivity less than that of the second heater 103. As a result, the heat generation in the conductive section 104 may be reduced.

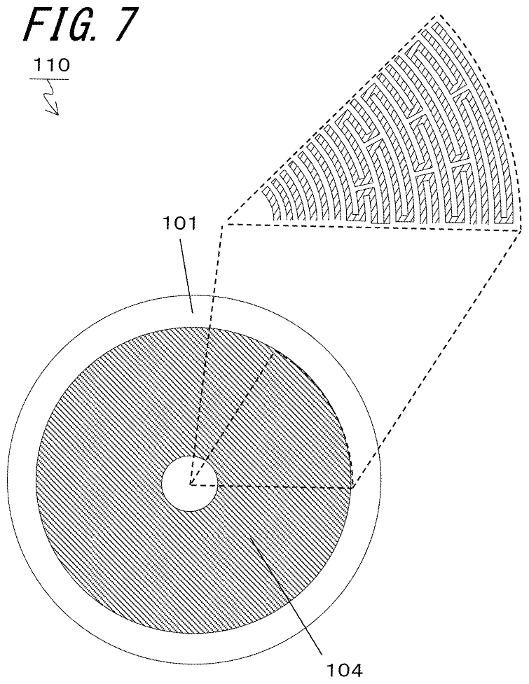

As shown in FIG. 7, in the sample holder 110 according to the disclosure, the conductive section 104 includes a portion extending in the circumferential direction of the first main surface and a portion extending in the radial direction of the first main surface. Accordingly, when the conductive section 104 itself generates heat, in the conductive section 104, both the portion extending in the circumferential direction of the sample holding surface 111 and the portion extending in the radial direction thereof generate heat. Therefore, compared to the example where the conductive section 104 includes only a portion extending in the radial direction of the sample holding surface 111, the region of the sample holding surface 111 to be heated by the conductive section 104 may be expanded. As a result, the unevenness of the heat generated in the sample holding surface 111 due to the heat generation of the conductive section 104 may be suppressed. As a result, the temperature uniformity of the sample holding surface 111 may be enhanced.

FIG. 7 is a plan view showing the second main surface of the sample holder 110, showing a pattern of the conductive section 104 in a partially enlarged manner. In the plan view of FIG. 7, the region where the conductive section 104 is located is shown with diagonal lines for better understanding. Likewise, in FIGS. 9, 11 and 13 which are also plan views, the region where the conductive section 104 provided is shown with diagonal lines for better understanding.

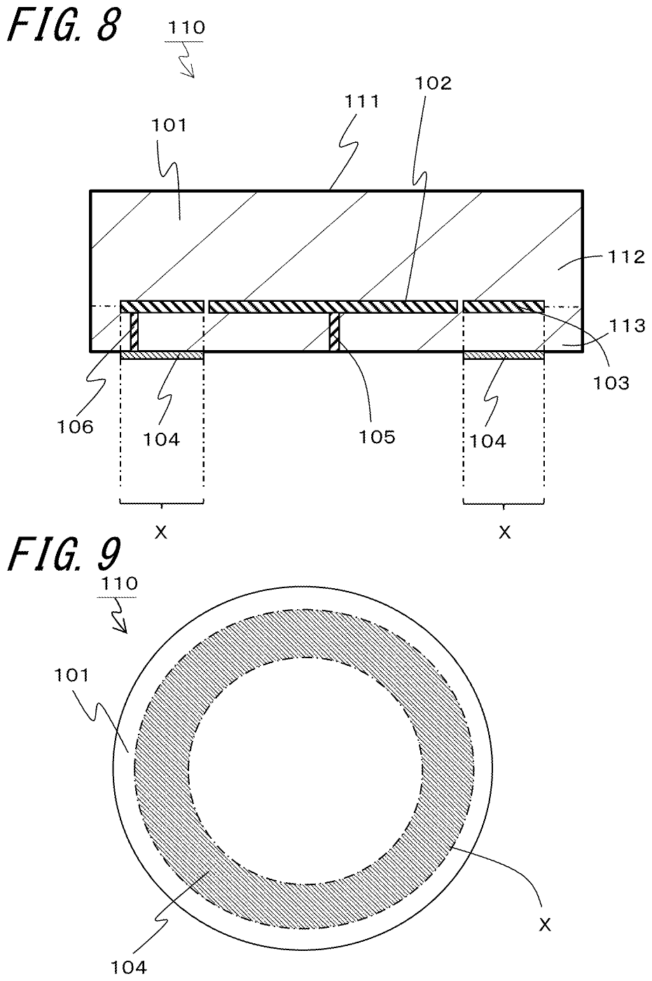

Further, as shown in FIG. 8, the region where the second heater 103 is located may be the same as the region where the conductive section 104 is located when viewed in the transparent plan view. As a result, it is possible that the region where the conductive section 104 generates heat and the region where the second heater 103 generates heat may be the same region when viewed in the transparent plan view. That is, the second heater 103 and the conductive section 104 may heat the same region of the sample holding surface 111. Therefore, by controlling the first heater 102 and the second heater 103 independently, the temperature of the sample holding surface 111 may be easily adjusted. As a result, the temperature uniformity of the sample holding surface 111 may be enhanced.

In the cross-sectional view shown in FIG. 8, the same region as the region where the second heater 103 is located is indicated by X when viewed in the transparent plan view. FIG. 9 is a plan view of the sample holder 110 shown in FIG. 8 viewed from the second main surface side, in which the conductive section 104 is located in the region X. In this example, the region where the second heater 103 is located means a region between an outer perimeter and an inner perimeter of the second heater 103. Further, the region where the conductive section 104 is located means a region within the outer perimeter when the conductive section 104 is formed in a circular shape. In addition, it means a region between the outer perimeter and the inner perimeter when the conductive section 104 is formed in an annular ring shape.

The region where the second heater 103 is located and the region where the conductive section 104 is located are not necessarily the same in a strict sense, and the regions may be said to be the same when 90% or more overlap with each other. For example, when viewed in the transparent plan view, the conducting portion 104 may include a portion extending with respect to the center side of the same region as the region where the second heater 103 is located, in a radial direction toward the center of the second main surface of the ceramic substrate 101. As a result, when the lead member is located at the other end of the conductive section 104, it may be electrically connected to the external power supply or the like at a position closer to the center.

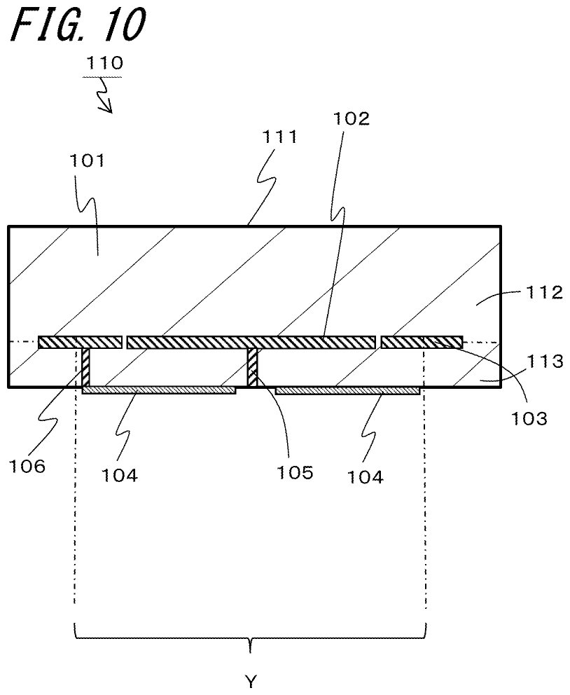

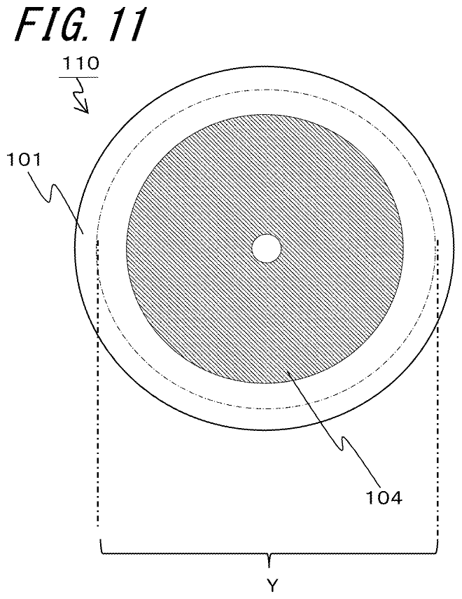

Further, as shown in FIG. 10, when viewed in the transparent plan view, the conductive section 104 is closer to the center side than the middle between the outer perimeter and the inner perimeter in the region where the second heater 103 is located, and may be provided in a region of the second main surface covering the entirety of the region where the first heater 102 is located. Accordingly, the region where the conductive section 104 generates heat can cover the region where the first heater 102 generates heat, when viewed in the transparent plan view. Therefore, by controlling the first heater 102 and the second heater 103 independently, the temperature of the sample holding surface 111 may be easily adjusted. As a result, the temperature uniformity of the sample holding surface 111 may be enhanced.

In the cross-sectional view shown in FIG. 10, in the region where the second heater 103 is located, a region closer to the center side than the middle between the outer perimeter and the perimeter is indicated by Y. FIG. 11 is a plan view of the sample holder 110 shown in FIG. 10 viewed from the second main surface side, in which the conductive section 104 is located in a region which covers the entirety of the region where the first heater 102 is located in the region Y. Further, the conductive section 104 is not necessarily located in the region which covers the entirety of the region where the first heater 102 is located in the region Y in a strict sense, and overlapping by 90% or more with the entire region will suffice. For example, in the center of the second main surface of ceramic substrate 101, there may be a region where the conductive section 104 is not located in order to electrically connect the through-hole conductor 105 to the external power supply.

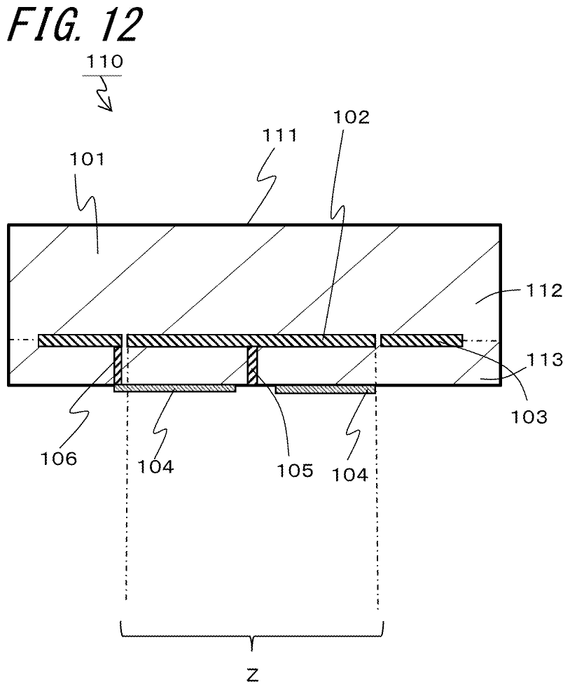

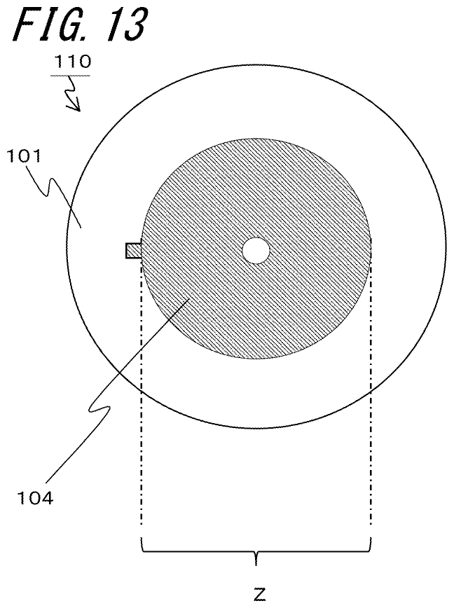

Further, as shown in FIG. 12, the region where the first heater 102 is located may be the same as the region where the conductive section 104 is located when viewed in the transparent plan view. Accordingly, it is possible that the region where the conductive section 104 generates heat and the region where the first heater 102 generates heat may be the same region when viewed in the transparent plan view. Therefore, by controlling the first heater 102 and the second heater 103 independently, the temperature of the sample holding surface 111 may be easily adjusted. As a result, the temperature uniformity of the sample holding surface 111 may be enhanced.

In the cross-sectional view shown in FIG. 12, the same region as the region where the first heater 102 is located is indicated by Z when viewed in the transparent plan view. FIG. 13 is a plan view of the sample holder 110 shown in FIG. 12 viewed from the second main surface side, in which the conductive section 104 is located in the region Z.

The region where the first heater 102 is located and the region where the conductive section 104 is located are not necessarily the same in a strict sense, and the regions may be said to be the same when 90% or more overlap with each other. For example, the portion of the conductive section 104 connected to the connection portion 106 may be outside the region Z when viewed in the transparent plan view.

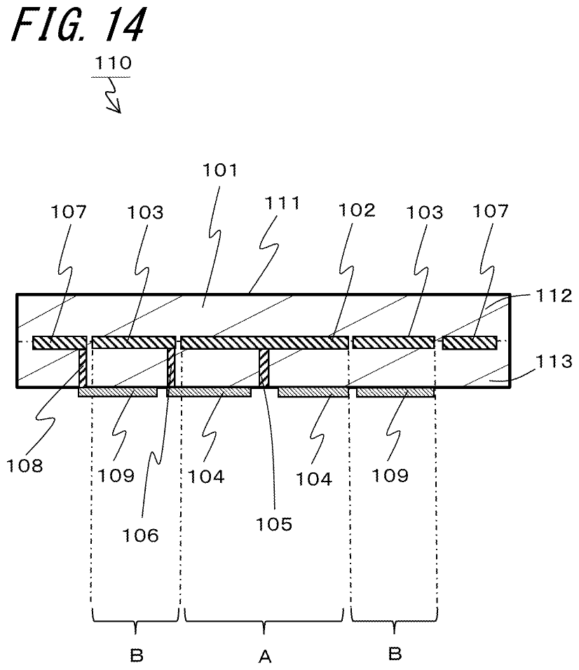

In addition, as shown in FIG. 14, there may be provided a third heater 107 which is distributed in a tubular shape to surround the second heater 103, a second connection portion 108 which is connected to the third heater 107 and is drawn out to the second main surface of the ceramic substrate 101, and a second conductive section 109 on the second main surface, which includes one end connected to the second connection portion 108 and the other end drawn out closer to the center side of the second main surface than the one end, in which, when viewed in the transparent plan view, the region where the first heater 102 is located and the region where the second conductive section 109 is located may be the same. As a result, even when the third heater 107 is provided, the temperature of the sample holding surface 111 may be easily adjusted. As a result, the temperature uniformity of the sample holding surface 111 may be enhanced.

### REFERENCE SIGNS LIST

1, 101: Ceramic substrate

11, 111: Sample holding surface

12, 112: First layer

13, 113: Second layer

14: Third layer

2, 102: First heater

3, 103: Second heater

4, 104: Conductive section

41: First portion

42: Second portion

5, 105: Through-hole conductor

106: Connection portion

107: Third heater

108: Second connection portion

109: Second conductive section

10, 110: Sample holder

1. A sample holder, comprising:
a ceramic substrate comprising a first circular main surface and a second circular main surface, the ceramic substrate comprising a first layer, a second layer and a third layer located in sequence;
a conductive section located between the second layer and the third layer, the conductive section comprising a portion extending in a circumferential direction of the first circular main surface and a portion extending in a radial direction of the first circular main surface;
a first heater located between the first layer and the second layer; and
a second heater located between the second layer and the third layer and connected to the conductive section, the second heater having an annular shape which surrounds the first heater and the conductive section when viewed in a transparent plan view of the sample holder.

2. The sample holder according to claim 1, wherein the portion extending in the circumferential direction of the conductive section comprises
a first portion located on a circumference of a first virtual circle, and a second portion located on a circumference of a second virtual circle, wherein the first virtual circle and the second virtual circle are concentric circles.

3. The sample holder according to claim 1, wherein the conductive section is located on the entire portion surrounded by the second heater.

4. The sample holder according to claim 1, wherein a thickness of the conductive section is less than a thickness of the second heater.

5. A sample holder, comprising:
a ceramic substrate comprising a first circular main surface and a second circular main surface, the ceramic substrate comprising a first layer and a second layer;
a first heater located between the first layer and the second layer;
a second heater located between the first layer and the second layer, the second heater having an annular shape which surrounds the first heater;
a connection portion which is connected to the second heater and is drawn out to the second circular main surface; and
a conductive section which comprises one end connected to the connection portion on the second circular main surface, another end located closer to a center side of the second circular main surface than the one end, a portion extending in a circumferential direction of the first circular main surface, and a portion extending in a radial direction of the first circular main surface.

6. The sample holder according to claim 5, wherein the second heater is located in a same region as the conductive section when viewed in the transparent plan view.

7. The sample holder according to claim 5, wherein, when viewed in the transparent plan view, the conductive section is closer to the center side than a middle between an outer perimeter and an inner perimeter in a region where the second heater is located, and the conductive section is located in a region of the second circular main surface covering the entirety of a region where the first heater is located.

8. The sample holder according to claim 7, wherein the first heater is located is a same region as the conductive section when viewed in the transparent plan view.
